(19) United States
(12) Patent Application Publication
(10) Pub. No.: US 2021/0005584 A1
(43) Pub. Date: Jan. 7, 2021

(54) METHOD AND APPARATUS FOR MANUFACTURING LED PANEL

(71) Applicant: SAMSUNG ELECTRONICS CO., LTD., Suwon-si (KR)

(72) Inventor: Youngmin CHO, Suwon-si (KR)

(73) Assignee: SAMSUNG ELECTRONICS CO., LTD., Suwon-si (KR)

(21) Appl. No.: 16/919,829

(22) Filed: Jul. 2, 2020

(30) Foreign Application Priority Data
Jul. 3, 2019 (KR) 10-2019-0079789

(51) Int. Cl. H01L 25/075; H01L 21/67; H01L 33/62; B25J 15/06; B65G 61/00

(52) U.S. Cl. CPC H01L 25/0753; H01L 21/67144; H01L 2933/0066; B25J 15/0616; B65G 61/00; H01L 33/62

(57) ABSTRACT

A method of manufacturing a light emitting diode (LED) panel including separating a plurality of LED chips from a wafer; mixing the plurality of LED chips; aligning the plurality of LED chips in a predetermined orientation; mounting the plurality of LED chips on a plurality of chip mounting portions of an alignment tray; picking up the plurality of LED chips mounted on the plurality of chip mounting portions of the alignment tray with a vacuum picker using vacuum pressure, each of the LED chips being pulled towards a respective receiving portion of a plurality of receiving portions of the vacuum picker; forming solders on the plurality of LED chips while the plurality of LED chips are disposed in the plurality of receiving portions of the vacuum picker; and releasing the vacuum pressure to mount the plurality of LED chips on a substrate.

### CROSS-REFERENCE TO RELATED APPLICATION

This application claims the benefit of Korean Patent Application No. 2019-0079789, filed on Jul. 3, 2019 in the Korean Intellectual Property Office, the disclosure of which is incorporated herein by reference.

### BACKGROUND

### 1. Field

The disclosure relates to a method and apparatus for manufacturing a light emitting diode (LED) panel, and more specifically, to a method and apparatus for manufacturing an LED panel capable of increasing yield and efficiency when transferring LED chips onto a substrate.

### 2. Description of the Related Art

A display device is a type of output device that visually displays data information, such as text, figures, and/or images, and includes televisions, various monitors, and various portable terminals (for example, notebook PCs, tablet PCs, and smart phones).

Display devices are classified into emissive type display devices that use a display panel capable of emitting light itself, such as an organic light emitting diode (OLED) and a non-emissive type display devices that use a display panel incapable of emitting light itself and thus needs to be supplied with light from a backlight unit, such as a liquid crystal panel (LCD).

A micro light emitting diode (referred to as a micro LED or μLED) display panel, which is a light emitting flat panel display panel, includes a plurality of inorganic light emitting diodes (inorganic LEDs) each having a size of 100 micrometers or less. Compared to LCD panels that require a backlight, the micro LED display panels provide better contrast, response time, and energy efficiency. Both the OLED and the micro LEDs (inorganic light emitting devices), have superior energy efficiency, but the micro LEDs have improved brightness, light emission efficiency, and lifespan compared to the OLEDs.

The micro LED display panel may be manufactured by transferring micro LED chips of several micrometers to hundreds of micrometers from a wafer onto a substrate.

The technique requires accurately and rapidly positioning micro LED chips of several micrometers to hundreds of micrometers from a wafer onto a substrate without damaging the micro LED chips.

### SUMMARY

In accordance with one aspect of the disclosure, a method of manufacturing a light emitting diode (LED) panel includes separating a plurality of LED chips from a wafer; mixing the plurality of LED chips; aligning the plurality of LED chips in a predetermined orientation; mounting the plurality of LED chips on a plurality of chip mounting portions of an alignment tray; picking up the plurality of LED chips mounted on the plurality of chip mounting portions of the alignment tray with a vacuum picker using vacuum pressure, each of the plurality of LED chips being pulled towards a respective receiving portion of a plurality of receiving portions of the vacuum picker; forming solders on the plurality of LED chips while the plurality of LED chips are disposed in the plurality of receiving portions of the vacuum picker; and releasing the vacuum pressure to mount the plurality of LED chips on a substrate.

The plurality of chip mounting portions may each be formed as a depression on an upper surface of the alignment tray.

The mounting the plurality of LED chips on the plurality of chip mounting portions of the alignment tray may include disposing a separate LED chip on each of the plurality of chip mounting portions.

The mounting the plurality of LED chips on the plurality of chip mounting portions of the alignment tray may include disposing a first portion of each LED chip in a respective chip mounting portion.

The plurality of chip mounting portions may be arranged in matrix form.

The plurality of receiving portions may each be formed as a depression on a lower surface of the vacuum picker.

The plurality of receiving portions may be formed at positions corresponding to positions of the plurality of chip mounting portions.

The picking up the plurality of LED chips may include pulling each LED chip into a respective receiving portion of the plurality of receiving portions.

The picking up the plurality of LED chips may include disposing a second portion of each LED chip in a respective receiving portion of the plurality of receiving portions.

The vacuum picker may include a plurality of suction holes formed through the vacuum picker, the suction holes being in fluid communication with the plurality of receiving portions.

The forming of the solders on the plurality of LED chips may include forming the solders on a solder mold; and moving the vacuum picker with the plurality of LED chips disposed thereon toward the solder mold and allowing the solders to be bonded to the plurality of LED chips.

The forming of the solders on the solder mold may include forming the solders on the solder mold at positions corresponding to positions of electrode pads of the plurality of LED chips.

The aligning of the plurality of LED chips may include aligning the plurality of LED chips facing in the predetermined orientation through a feeder.

The mounting of the plurality of LED chips on the plurality of chip mounting portions of the alignment tray may include picking up the plurality of LED chips aligned to face in the predetermined orientation through the feeder and mounting the picked-up plurality of LED chips on the plurality of chip mounting portions of the alignment tray.

In accordance with another aspect of the disclosure, an apparatus for manufacturing a light emitting diode (LED) panel includes an alignment tray having a plurality of chip mounting portions on which a plurality of LED chips are mounted; and a vacuum picker having a plurality of receiving portions configured to pull in the plurality of LED chips mounted on the plurality of chip mounting portions of the alignment tray using vacuum pressure.

The plurality of chip mounting portions may each be formed as a depression on an upper surface of the alignment tray, and the plurality of receiving portions may each be formed as a depression on a lower surface of the vacuum picker.

The plurality of chip mounting portions may be formed at positions corresponding to positions of the plurality of receiving portions.

A separate LED chip may be mounted on each of the plurality of chip mounting portions, and a separate LED chip may be disposed on each of the plurality of receiving portions.

A first portion of each LED chip may be disposed in a respective chip mounting portion of the plurality of chip mounting portions, and a second portion of each LED chip may be disposed in a respective receiving portion of the plurality of receiving portions.

### BRIEF DESCRIPTION OF THE DRAWINGS

The above and other aspects and features of certain embodiments of the present disclosure will become apparent and more readily appreciated from the following description taken in conjunction with the accompanying drawings, in which:

FIG. 1 is a perspective view showing an external appearance of a display device according to an embodiment;

FIG. 2 is a perspective view showing a display device according to an embodiment, which shows a state in which a frame and an LED panel are disassembled;

FIG. 3 is a flow chart showing a method of manufacturing a LED panel according to an embodiment;

FIG. 4 is a perspective view showing an operation of mounting a plurality of LED chips on an alignment tray according to an embodiment;

FIG. 5 is a perspective view showing an operation of picking up LED chips mounted on an alignment tray with a vacuum picker according to an embodiment;

FIG. 6 is a bottom perspective view showing a vacuum picker according to an embodiment;

FIG. 7 is a cross-sectional view showing an operation of a vacuum picker descending over an alignment tray according to an embodiment;

FIG. 8 is a view showing an operation of a vacuum picker approaching an alignment tray and picking up LED chips mounted on the alignment tray according to an embodiment;

FIG. 9 is an enlarged view of portion ‘0’ of FIG. 8;

FIG. 10 is a view showing an operation of a vacuum picker moving over a solder mold according to an embodiment;

FIG. 11 is a view showing an operation of a vacuum picker approaching a solder mold and bonding solders to LED chips according to an embodiment;

FIG. 12 is a view showing an operation of a vacuum picker moving over a substrate according to an embodiment;

FIG. 13 is a view showing an operation of a vacuum picker approaching a substrate and mounting LED chips on the substrate according to an embodiment; and

FIG. 14 is a view showing an operation of a vacuum picker being separated from a substrate according to an embodiment.

### DETAILED DESCRIPTION

The embodiments set forth herein and illustrated in the configuration of the present disclosure are only the most preferred embodiments and are not representative of the full the scope of the present disclosure, so it should be understood that they may be replaced with various equivalents and modifications at the time of the disclosure.

The terminology used herein is for the purpose of describing particular embodiments only and is not intended to limit the disclosure. It is to be understood that the singular forms “a,” “an,” and “the” include plural references unless the context clearly dictates otherwise. In the drawings, unrelated parts may be not shown and the sizes of components may be exaggerated for clarity.

It will be further understood that the terms “include”, “comprise” and/or “have” when used in this specification, specify the presence of stated features, integers, steps, operations, elements, and/or components, but do not preclude the presence or addition of one or more other features, integers, steps, operations, elements, components, and/or groups thereof.

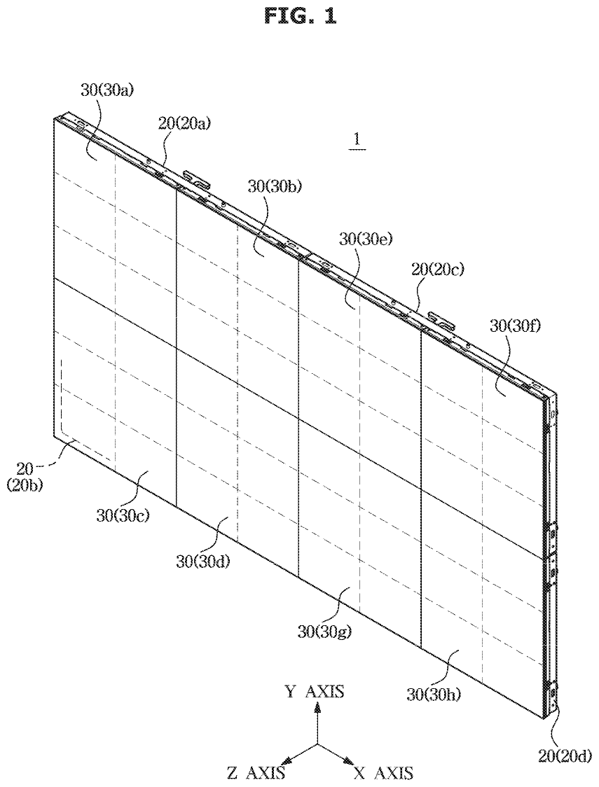

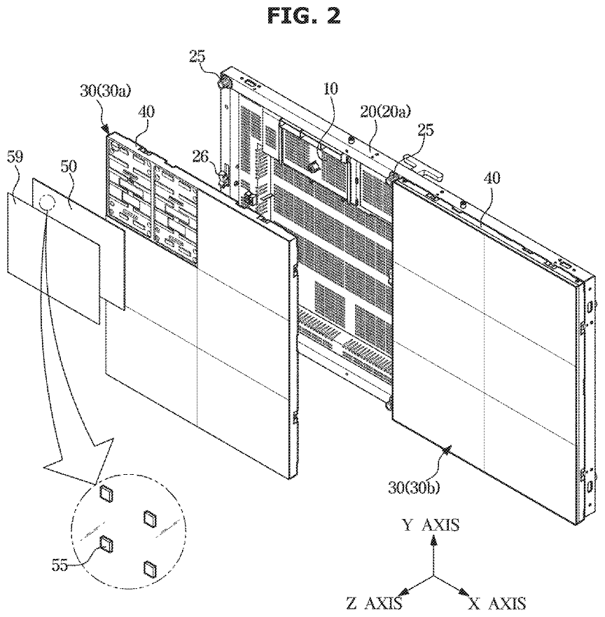

The terms “front”, “rear”, “upper”, “lower”, “top”, and “bottom” as herein used are defined with respect to the accompanying drawings, such as FIGS. 1 and 2. In FIGS. 1 and 2, X-axis, Y-axis, and Z-axis directions perpendicular to each other are illustrated, the X-axis direction refers to the left-right direction, the Y-axis direction refers to the up-down direction, and the Z-axis direction refers to the front-rear direction.

Hereinafter, a preferred embodiment of the disclosure will be described in detail with reference to the accompanying drawings.

FIG. 1 is a perspective view showing the external appearance of a display device according to an embodiment. FIG. 2 is an exploded view showing a display device according to an embodiment, which shows a state in which a frame and an LED panel are disassembled.

Referring to FIGS. 1 and 2, a display device 1 displays information, data, materials, and the like in the form of text, figures, graphs, images, and the like, and may include a billboard, an electronic display, a screen, a television, a monitor, and the like. The display device may be installed on a wall or ceiling, or may be installed on an indoor or outdoor ground by a stand.

The display device 1 may include light emitting diode (LED) panels 30 and frames 20 coupled to the rear sides of the LED panels 30 to support the LED panels 30. In the embodiment shown in FIGS. 1 and 2, the display device 1 includes eight LED panels 30a to 30h and four frames 20a to 20d coupled to the LED panels 30a to 30h. That is, two LED panels 30 may be coupled to one frame 20.

First and second LED panels 30a and 30b are coupled to a first frame 20a, third and fourth LED panels 30c and 30d are coupled to a second frame 20b, fifth and sixth LED panels 30e and 30f are coupled to a third frame 20c, and seventh and eighth LED panels 30g and 30h are coupled to a fourth frame 20d. However, the number of frames and LED panels constituting the display device 1 is not limited thereto.

The frame 20 may be formed in a shape that matches a perimeter of the attached LED panels 30. The LED panels 30 may be coupled to the frame 20 through a magnetic fastening device 25. The magnetic fastening device 25 may hold the LED panels 30 in close contact with the frame 20 by a magnetic force of a magnet.

A rear cover 10 may be coupled to an open rear side of the frame 20. Between the LED panels 30 and the rear cover 10, a control board for driving the LED panels 30 and a power supply device for supplying power to the LED panels 30 may be disposed.

The display device 1 may further include a latch 26 to prevent the LED panels 30 from being separated from the frames 20.

The LED panels 30 may be arranged to be adjacent to each other in the upper side and lower side direction (Y-axis direction) and/or the left side and right side direction (X-axis direction). That is, the LED panels 30 may be arranged in the form of an M*N matrix. In the embodiment shown in FIGS. 1-2, the eight LED panels 30 are arranged in a 4*2 matrix form.

The LED panel 30 may include substrates 50 and a bracket 40 to which the substrates 50 are attached. In the embodiment shown in FIGS. 1-2, the LED panel 30 includes six substrates 50 and one bracket 40.

That is, the six substrates 50 may be attached to the one bracket 40. However, the number of the substrates 50 attached to the bracket 40 is not limited. Unlike the embodiment shown in FIGS. 1-2, only one substrate 50 may be attached to one bracket 40, or a different number of substrates 50 may be attached to one bracket 40. The substrate 50 may be attached to a front surface of the bracket 40 through an adhesive, a double-sided adhesive tape, or the like.

A plurality of LED chips 55 may be mounted on the substrate 50, and a protective member 59 may be provided on the substrate 50 to protect the plurality of LED chips 55 or improve optical performance.

The substrate 50 may be formed of a material, such as glass, polyimide (PI), or flame retardant 4(FR4). A black layer may be formed on the front surface of the substrate 50 to absorb external light to improve contrast.

The plurality of LED chips 55 may include a red LED, a green LED, and a blue LED as sub-pixels. The red LED, the green LED, and the blue LED may form a single pixel in cooperation with each other. The plurality of LED chips 55 may be arranged in a certain shape. That is, the red LED, the green LED, and the blue LED may be arranged in a line with each other, or may be arranged in a triangular shape.

The plurality of LED chips 55 may include a micro LED formed of an inorganic material and having a widthwise length, a lengthwise length, and a height in a range of several micrometers to hundreds of micrometers. The plurality of LED chips 55 may be collected from a silicon wafer and transferred to the substrate 50. A method of transferring the plurality of LED chips 55 to the substrate 50 according to an embodiment will be described below.

The protective member 59 may be formed of a light-transmitting or fluorescent material, such as an acrylic resin, a polyimide resin, an epoxy resin, a polyurethane resin, and the like, and may be formed to cover the plurality of LED chips 55 mounted on the substrate 50. The protective member 59 may be collectively formed to cover the plurality of LED chips 55 after all of the plurality of LED chips 55 are mounted on the substrate 50.

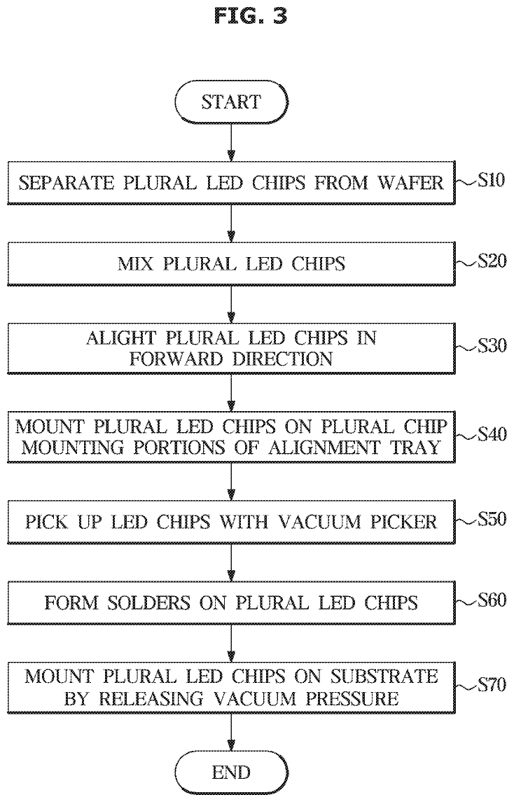

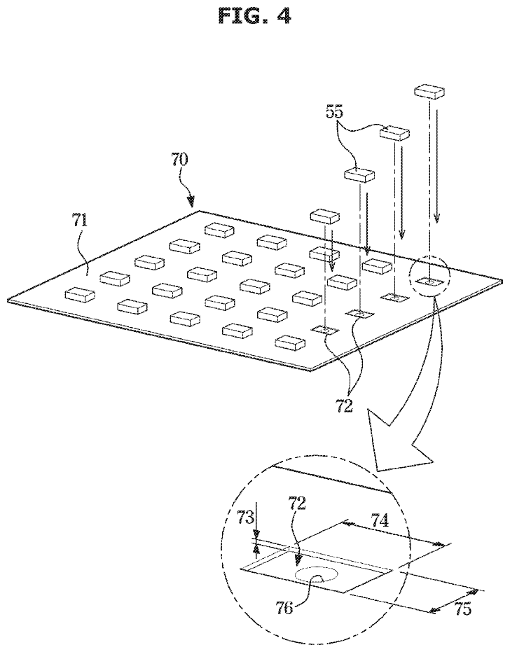

FIG. 3 is a flow chart showing a method of manufacturing a LED panel according to an embodiment. FIG. 4 is a perspective view showing an operation of mounting a plurality of LED chips on an alignment tray according to an embodiment.

Referring to FIGS. 3 and 4, the method of manufacturing the LED panel according to an embodiment will be described.

The method of manufacturing the LED panel according to an embodiment may include separating the plurality of LED chips 55 from a wafer (operation S10), and mixing the separated LED chips 55 (operation S20).

The wavelength bands of the plurality of LED chips 55 separated from the wafer may be different from each other depending on the separated positions thereof, and the difference in the wavelength band may cause gradation in an image when the plurality of LED chips 55 separated from the wafer are transferred to the substrate in the same positions as they are on the wafer.

According to the method of manufacturing the LED panel according to an embodiment, the plurality of LED chips 55 separated from the wafer are mixed such that the plurality of LED chips 55 are uniformly and evenly transferred to the substrate. The plurality of LED chips 55 may be mixed through an automatic mixer configured to rotate and revolve, or may be manually mixed.

The evenly mixed plurality of LED chips 55 may be aligned in a predetermined orientation through a feeder (operation 30).

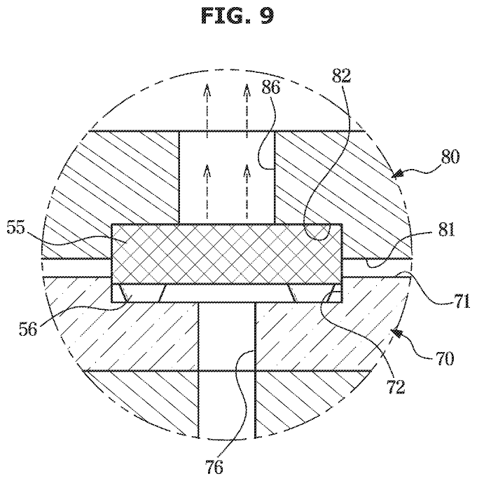

For example, the plurality of LED chips 55 may be arranged such that electrode pads (56 in FIG. 9) thereof face downward. In addition, the plurality of LED chips 55 may be arranged such that an n-type electrode pad and a p-type electrode pad are disposed in a predetermined direction.

The feeder may be provided using a bowl feeder having a bowl for accommodating the plurality of LED chips 55, a spiral path formed on an outer portion of the bowl in the form of an upward spiral, and a motor for vibrating the bowl, or a line feeder or the like.

The method of manufacturing the LED panel according to an embodiment may include mounting the plurality of LED chips 55 to a plurality of chip mounting portions 72 of an alignment tray 70 (operation 40).

The plurality of LED chips 55 aligned in the predetermined orientation through the feeder may be picked up and mounted on the plurality of chip mounting portions 72 of the alignment tray 70.

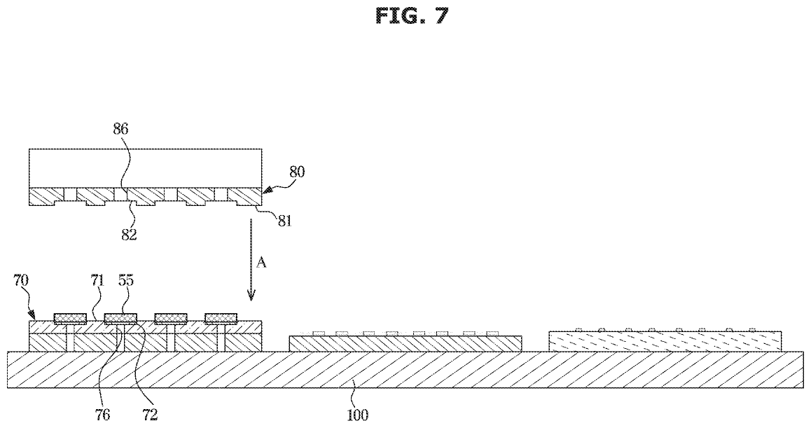

The alignment tray 70 first may allow the plurality of LED chips 55 to be aligned on correct positions. The alignment tray 70 is configured to simultaneously mount a large number of the LED chips 55, so that the large number of the LED chips 55 may be simultaneously transferred to the substrate 50. The alignment tray 70 may be disposed on a stage 100 (shown in FIG. 7).

The alignment tray 70 may be formed in a substantially flat plate shape. The alignment tray 70 may have the plurality of chip mounting portions 72 on which the plurality of LED chips 55 are mounted. One LED chip 55 may be mounted on each of the chip mounting portions 72. The plurality of chip mounting portions 72 may be formed at positions corresponding to positions where the plurality of LED chips 55 are intended to be mounted on the substrate 50.

For example, when the plurality of LED chips 55 are intended to be mounted on the substrate 50 in a matrix form at a predetermined interval, the plurality of chip mounting portions 72 of the alignment tray 70 may be also formed in a matrix form at the same interval as the interval of the plurality of LED chips 55.

The alignment tray 70 may have an upper surface 71 formed flat. The plurality of chip mounting portions 72 may be formed in depressions formed on the upper surface 71 of the alignment tray 70. Each of the chip mounting portions 72 may be generally formed in a shape corresponding to the shape of the LED chip 55. For example, each of the chip mounting portions 72 may be formed in a hexahedral shape having a predetermined height 73, a predetermined length 74, and a predetermined width 75.

The length 74 and the width 75 of the chip mounting portion 72 may be formed to be equal to or slightly larger than those of the LED chip 55. Accordingly, the LED chip 55 disposed in the chip mounting portion 72 may be prevented from moving or rotating.

However, the height 73 of the chip mounting portion 72 may be formed to be smaller than the height of the LED chip 55 such that an upper portion of the LED chip 55 may not be fully disposed in the chip mounting portion 72. That is, only a lower portion of the LED chip 55 is disposed in each chip mounting portion 72 and an upper portion of the LED chip 55 may protrude upward of the chip mounting portion 72. The portion protruding upward of the chip mounting portion 72 may be disposed in an receiving portion 82 of a vacuum picker 80 to be described below.

The alignment tray 70 may include a through hole 76 formed to pass through the alignment tray 70 so as to be connected to the chip mounting portion 72. When the LED chip 55 is mounted on the chip mounting portion 72, a vacuum pressure is provided through the through hole 76 so that the LED chip 55 is more stably and accurately mounted on the chip mounting portion 72.

As described above, by mounting the plurality of LED chips 55 on the plurality of chip mounting portions 72 of the alignment tray 70, the plurality of LED chips 55 may be aligned to the correct positions. In addition, the alignment tray 70 includes a large number of the chip mounting portions 72, allowing a large number of the LED chips 55 mounted on the alignment tray 70 to be simultaneously vacuum-adsorbed and transported with the vacuum picker 80 to be described below.

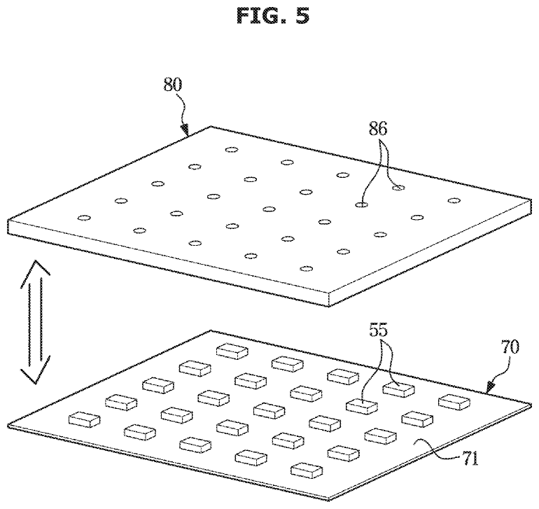

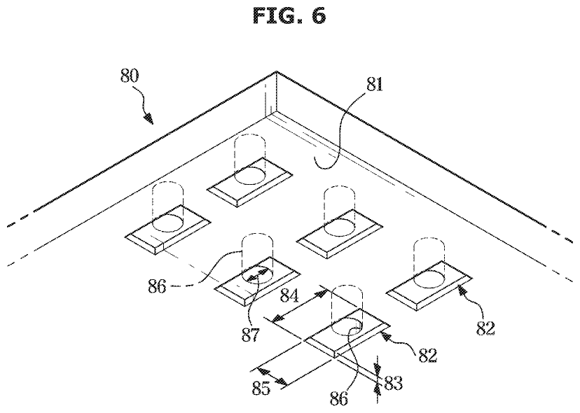

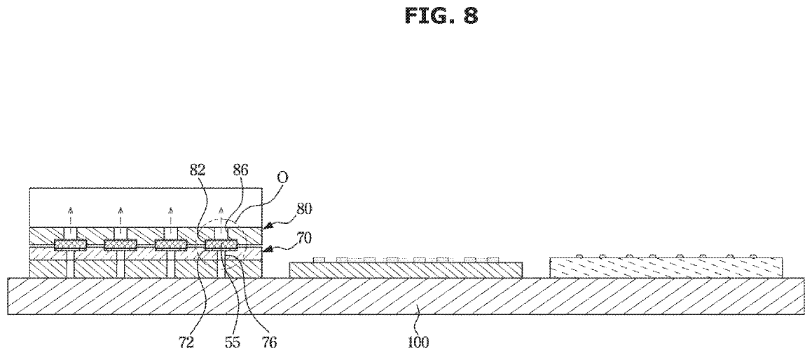

FIG. 5 is a perspective view showing an operation of picking up LED chips mounted on an alignment tray with a vacuum picker according to an embodiment. FIG. 6 is a bottom perspective view showing a vacuum picker according to an embodiment. FIG. 7 is a cross-sectional view showing an operation of a vacuum picker descending over an alignment tray according to an embodiment. FIG. 8 is a view showing an operation of a vacuum picker approaching an alignment tray and picking up LED chips mounted on the alignment tray according to an embodiment. FIG. 9 is an enlarged view of portion ‘O’ of FIG. 8.

Referring to FIGS. 5 to 9 in conjunction with FIG. 3, a process of picking up LED chips using a vacuum picker according to an embodiment will be described.

The method of manufacturing the LED panel according to an embodiment may include picking up the plurality of LED chips 55 mounted on the plurality of chip mounting portions 72 of the alignment tray 70 with the plurality of receiving portions 82 of the vacuum picker 80 using a vacuum pressure (operation S50).

The vacuum picker 80 may provide the plurality of receiving portions 82 for picking up the plurality of LED chips 55 on the plurality of chip mounting portions 72 of the alignment tray 70 using vacuum pressure.

The vacuum picker 80 may have a lower surface 81 formed flat to be parallel to the upper surface 71 of the alignment tray 70. The plurality of receiving portions 82 may be formed in as depressions on the lower surface 81 of the vacuum picker 80. The plurality of receiving portions 82 of the vacuum picker 80 may be formed at positions corresponding to the positions of the plurality of chip mounting portions 72 of the alignment tray 70.

That is, in the same way as the plurality of chip mounting portions 72 are formed at positions corresponding to the positions where the plurality of LED chips 55 are intended to be mounted on the substrate 50, the plurality of receiving portions 82 are also formed at positions corresponding to positions where the plurality of LED chips 55 are intended to be mounted on the substrate 50.

For example, when the plurality of LED chips 55 are intended to be mounted in matrix form at predetermined intervals on the substrate 50, the plurality of receiving portions 82 may also be formed in matrix form at the same intervals as that of the plurality of LED chips 55.

One LED chip 55 may be sucked into each of the plurality of receiving portions 82. Each of the receiving portions 82 may be formed in a shape corresponding to the shape of the LED chip 55. For example, each receiving portion 82 may be formed in a hexahedral shape having a predetermined height 83, a predetermined length 84, and a predetermined width 85.

The length 84 and the width 85 of the receiving portion 82 may be equal to or slightly larger than the length and width of the LED chip 55. Accordingly, the LED chip 55 disposed in the receiving portion 82 may be prevented from moving or rotating.

The height 83 of the receiving portion 82 may be smaller than the height of the LED chip 55. Therefore, only the upper portion of the LED chip 55 may be disposed in the receiving portion 82.

The vacuum picker 80 may include suction holes 86 formed to pass through the vacuum picker 80 so as to be connected to the receiving portions 82. The suction hole 86 may have a predetermined size suitable for smoothly sucking the LED chip 55 into the absorption portion 82. For example, the suction hole 86 may have a diameter 87 of 80 to 100 micrometers.

The vacuum picker 80 may descend to approach the alignment tray 70 (A). When the LED chips 55 are disposed in the receiving portions 82, a vacuum pressure may be applied to the suction holes 86. When the vacuum pressure is applied through the suction holes 86, the LED chips 55 may be sucked to the receiving portions 82.

As described above, since the LED chips 55 are sucked into the vacuum picker 80 using a vacuum pressure, a great physical impact is not imparted on to the LED chips 82, and damage to the LED chips 82 is prevented or minimized.

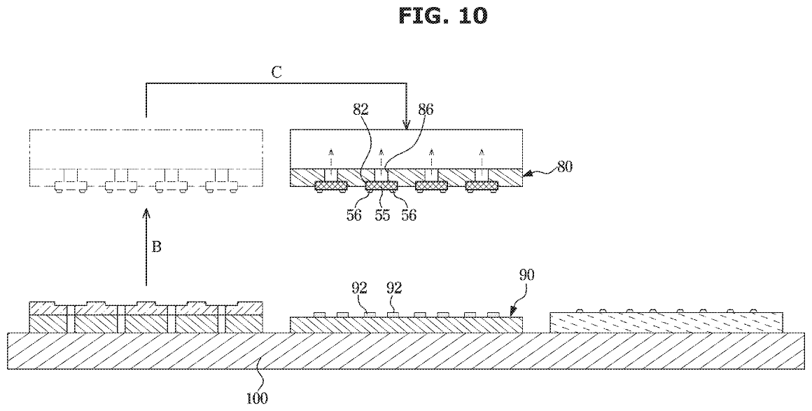

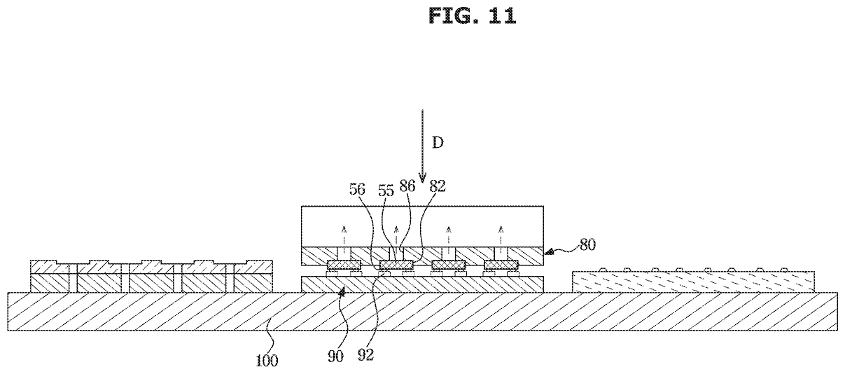

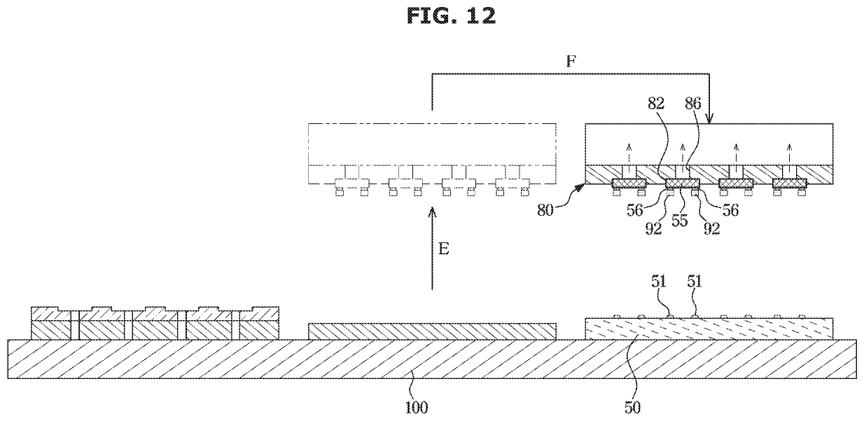

FIG. 10 is a view showing an operation of a vacuum picker moving over a solder mold according to an embodiment. FIG. 11 is a view showing an operation of a vacuum picker approaching a solder mold and bonding solders to LED chips according to an embodiment. FIG. 12 is a view showing an operation of a vacuum picker moving over a substrate according to an embodiment.

Referring to FIGS. 10 to 12 in conjunction with FIG. 3, a method of forming solders 92 on the plurality of LED chips 55 according to an embodiment will be described.

The method of manufacturing the LED panel according to an embodiment includes forming the solders 92 on the plurality of LED chips 55 while the plurality of LED chips 55 are held in the plurality of receiving portions 82 of the vacuum picker 70 (operation S60).

The method of manufacturing the LED panel according to an embodiment may include preparing a solder mold 90 and forming the solders 92 on the solder mold 90. The solder mold 90 may be disposed on the stage 100.

When forming the solders 92 on the solder mold 90, the solders 92 may be formed on the solder mold 90 so as to correspond to the positions of electrode pads 56 of the plurality of LED chips 55.

After the solders 92 are formed on the solder mold 90, the vacuum picker 80 with the plurality of LED chips 55 held thereon may move toward the solder mold 90 (movement C).

The vacuum picker 80 may descend to approach the solder mold 90, and the solders 92 may come into contact with the electrode pads 56 of the plurality of LED chips 55 (movement D).

When the solders 92 are pressed against the electrode pads 56 of the plurality of LED chips 55, the solders 92 may be bonded to the electrode pads 56 of the plurality of LED chips 55. To this end, the solders 92 may have a greater adhesion to the electrode pads 56 than the solder mold 90.

With respect to the contact between the electrode pads 56 and the solders 92, a flux treatment may be performed to remove foreign substances of the electrode pads 56 and increase the adhesion between the electrode pads 56 and the solders 92.

When the solders 92 are bonded to the electrode pads 56, the vacuum picker 80 may ascend to be separated from the solder mold 90 (movement E). The vacuum picker 80 may move over the substrate 50 while maintaining the suction connection with the plurality of LED chips 55 on which the solders 92 are formed.

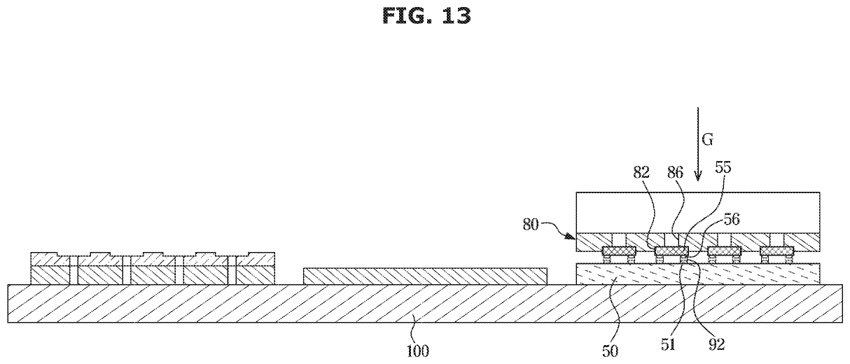

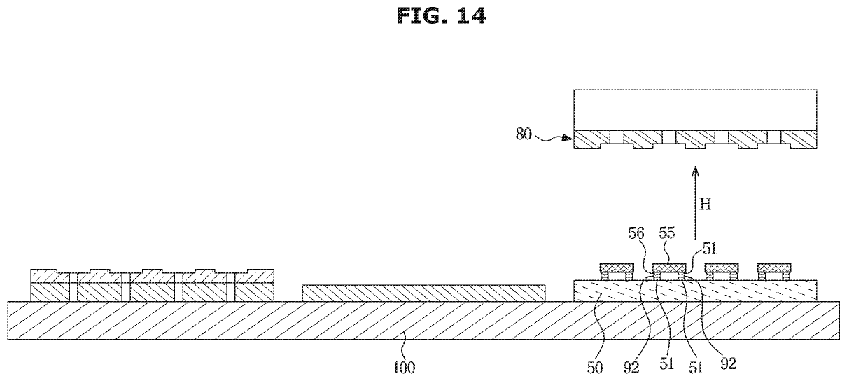

FIG. 13 is a view showing an operation of a vacuum picker approaching a substrate and mounting LED chips on the substrate according to an embodiment. FIG. 14 is a view showing an operation of a vacuum picker being separated from a substrate according to an embodiment.

Referring to FIGS. 13 and 14 in conjunction with FIG. 3, a method of mounting the plurality of LED chips on the substrate by releasing the vacuum pressure of the vacuum picker according to an embodiment will be described.

The method of manufacturing the LED panel according to the embodiment may include mounting the plurality of LED chips 55 on the substrate 50 by releasing the vacuum pressure of the vacuum picker 80 (operation 70). The substrate 50 may be disposed on the stage 100.

The vacuum picker 80 may descend to approach the substrate 50 while maintaining a suction connection with the plurality of LED chips 55 on which the solders 92 are formed (movement G). The solders 92 formed on the plurality of LED chips 55 may come into contact with substrate electrodes 51 of the substrate 50.

When the solders 92 formed on the plurality of LED chips 55 come into contact with the substrate electrodes 51 of the substrate 50, the vacuum pressure of the vacuum picker 80 is released, and the vacuum picker 80 is separated from the substrate 50 (movement H). Accordingly, the plurality of LED chips 55 may be mounted on the substrate 50.

As is apparent from the above, according to an aspect, an LED panel can be manufactured by transferring micro LED chips having a size of several micrometers to hundreds of micrometers collected from a wafer onto a substrate.

According to an aspect, damage to the LED chips in the process of transferring the LED chips onto the substrate can be prevented or minimized.

According to an aspect, a plurality of LED chips can be transferred onto the substrate rapidly, accurately, and easily.

A display module can be installed and applicable to a wearable device, a portable device, a handheld device, or other electronic products and electrical parts, which require various displays, as a single unit, and can be applicable to display devices, such as a personal computer (PC) monitor, high-definition TV and signage, and electronic displays, as a matrix type through a plurality of assembly arrangements.

Although few embodiments of the disclosure have been shown and described, the above embodiments are for illustrative purpose only, and it would be appreciated by those skilled in the art that changes and modifications may be made in these embodiments without departing from the principles and scope of the disclosure, the scope of which is defined in the claims and their equivalents.

What is claimed is:

1. A method of manufacturing a light emitting diode (LED) panel, the method comprising:
separating a plurality of LED chips from a wafer;
mixing the plurality of LED chips;
aligning the plurality of LED chips in a predetermined orientation;
mounting the plurality of LED chips on a plurality of chip mounting portions of an alignment tray;
picking up the plurality of LED chips mounted on the plurality of chip mounting portions of the alignment tray with a vacuum picker using vacuum pressure, each of the plurality of LED chips being pulled toward a respective receiving portion of a plurality of receiving portions of the vacuum picker;
forming solders on the plurality of LED chips while the plurality of LED chips are disposed in the plurality of receiving portions of the vacuum picker; and
releasing the vacuum pressure to mount the plurality of LED chips on a substrate.

2. The method of claim 1, wherein the plurality of chip mounting portions are each formed as a depression on an upper surface of the alignment tray.

3. The method of claim 1, wherein the mounting the plurality of LED chips on the plurality of chip mounting portions of the alignment tray comprises disposing a separate LED chip on each of the plurality of chip mounting portions.

4. The method of claim 1, wherein the mounting the plurality of LED chips on the plurality of chip mounting portions of the alignment tray comprises disposing a first portion of each LED chip in a respective chip mounting portion.

5. The method of claim 1, wherein the plurality of chip mounting portions are arranged in matrix form.

6. The method of claim 1, wherein the plurality of receiving portions are each formed as a depression on a lower surface of the vacuum picker.

7. The method of claim 1, wherein the plurality of receiving portions are formed at positions corresponding to positions of the plurality of chip mounting portions.

8. The method of claim 1, wherein the picking up the plurality of LED chips comprises pulling each LED chip towards a respective receiving portion of the plurality of receiving portions.

9. The method of claim 4, wherein the picking up the plurality of LED chips comprises disposing a second portion of each LED chip in a respective receiving portion of the plurality of receiving portions.

10. The method of claim 1, wherein the vacuum picker comprises a plurality of suction holes formed through the vacuum picker, the suction holes being in fluid communication with the plurality of receiving portions.

11. The method of claim 1, wherein the forming of the solders on the plurality of LED chips comprises:
forming the solders on a solder mold; and
moving the vacuum picker with the plurality of LED chips disposed thereon toward the solder mold and allowing the solders to be bonded to the plurality of LED chips.

12. The method of claim 11, wherein the forming of the solders on the solder mold comprises forming the solders on the solder mold at positions corresponding to positions of electrode pads of the plurality of LED chips.

13. The method of claim 1, wherein the aligning of the plurality of LED chips in the predetermined orientation comprises aligning the plurality of LED chips in the predetermined orientation through a feeder.

14. The method of claim 13, wherein the mounting of the plurality of LED chips on the plurality of chip mounting portions of the alignment tray comprises:
picking up the plurality of LED chips aligned in the predetermined orientation through the feeder and mounting the picked-up plurality of LED chips on the plurality of chip mounting portions of the alignment tray.

15. An apparatus for manufacturing a light emitting diode (LED) panel, the apparatus comprising:
an alignment tray having a plurality of chip mounting portions on which a plurality of LED chips are mounted; and
a vacuum picker having a plurality of receiving portions configured to pull in the plurality of LED chips mounted on the plurality of chip mounting portions of the alignment tray using vacuum pressure.

16. The apparatus of claim 15, wherein the plurality of chip mounting portions are each formed as a depression on an upper surface of the alignment tray, and the plurality of receiving portions are each formed as a depression on a lower surface of the vacuum picker.

17. The apparatus of claim 15, wherein the plurality of chip mounting portions are formed at positions corresponding to positions of the plurality of receiving portions.

18. The apparatus of claim 15, wherein a separate LED chip is mounted on each of the plurality of chip mounting portions, and a separate LED chip is disposed on each of the plurality of receiving portions.

19. The apparatus of claim 15, wherein a first portion of each LED chip is disposed in a respective chip mounting portion of the plurality of chip mounting portions, and a second portion of each LED chip is disposed in a respective receiving portion of the plurality of receiving portions.
